(19) United States
(12) Patent Application Publication
(10) Pub. No.: US 2022/0403516 A1
(43) Pub. Date: Dec. 22, 2022

(54) REACTOR SYSTEM AND METHOD FOR FORMING A LAYER COMPRISING INDIUM GALLIUM ZINC OXIDE

(71) Applicant: ASM IP Holding B.V., Almere (NL)

(72) Inventors: Paul Ma, Scottsdale, AZ (US); Eric Shero, Phoenix, AZ (US); Todd Dunn, Cave Creek, AZ (US); Jonathan Bakke, Phoenix, AZ (US); Jereld Winkler, Gilbert, AZ (US); Xingye Wang, Gilbert, AZ (US); Eric Jen Cheng Liu, Phoenix, AZ (US)

(21) Appl. No.: 17/842,007

(22) Filed: Jun. 16, 2022

Related U.S. Application Data
(60) Provisional application No. 63/213,061, filed on Jun. 21, 2021.

(51) Int. Cl. C23C 16/455; C23C 16/02; C23C 16/40; C23C 16/56

(52) U.S. Cl. CPC C23C 16/45553; C23C 16/02; C23C 16/407; C23C 16/56

(57) ABSTRACT

Reactor systems and methods for forming a layer comprising indium gallium zinc oxide are disclosed. The layer comprising indium gallium zinc oxide can be formed using one or more reaction chambers of a process module.

### CROSS-REFERENCE TO RELATED APPLICATIONS

This application is a non-provisional of, and claims priority to and the benefit of, U.S. Provisional Patent Application No. 63/213,061, filed Jun. 21, 2021 and entitled “REACTOR SYSTEM AND METHOD FOR FORMING A LAYER COMPRISING INDIUM GALLIUM ZINC OXIDE,” which is hereby incorporated by reference herein.

### FIELD OF DISCLOSURE

The present disclosure generally relates to gas-phase reactors and systems. More particularly, the disclosure relates to reactor systems including a plurality of reaction chambers and to methods of using the reactor systems.

### BACKGROUND OF THE DISCLOSURE

Gas-phase processes, such as chemical vapor deposition (CVD), plasma-enhanced CVD (PECVD), atomic layer deposition (ALD), plasma-enhanced ALD (PEALD), atomic layer etch (ALE), and the like are often used to deposit materials onto a surface of a substrate, etch materials from a surface of a substrate, and/or clean or treat a surface of a substrate. For example, gas-phase processes can be used to deposit or etch layers on a substrate to form semiconductor devices, flat panel display devices, photovoltaic devices, microelectromechanical systems (MEMS), and other electronic devices.

Typically, multiple gas-phase processes are used to form such devices. Often, each process is carried out in its own reactor system or module and transferred to another reactor system or module for subsequent processing. Dedicating a reactor system or module to each process is desirable to prevent or mitigate cross contamination of reactants used or products formed within the reactor. However, using dedicated reactor systems or modules requires significant capital costs and increases operating costs associated with making the devices. In addition, processing substrates in different reactor systems and modules often requires a vacuum and/or air break to remove a substrate from one reactor system or module and place the substrate in another reactor system or module.

Recently, interest has grown in depositing layers including indium gallium zinc oxide. Layers of indium gallium zinc oxide can be used to form a variety of devices, including, for example, thin-film transistors in displays formed using amorphous indium gallium zinc oxide. Often, the indium gallium zinc oxide is deposited by sputtering material from a target of indium gallium zinc oxide. While such techniques work well for some applications, there is a general desire to deposit indium gallium zinc oxide in a more controlled and/or more conformal manner. Furthermore, interest has grown in developing other devices, such as other transistors and memory devices, using amorphous or crystalline indium gallium zinc oxide with improved properties. Accordingly, improved reactor systems and methods suitable for depositing indium gallium zinc oxide are desired.

Any discussion of problems and solutions involved in the related art has been included in this disclosure solely for the purposes of providing a context for the present disclosure, and should not be taken as an admission that any or all of the discussion was known at the time the invention was made.

### SUMMARY OF THE DISCLOSURE

Various embodiments of the present disclosure relate to reactor systems and to methods of using the reactor systems. While the ways in which the reactor systems and methods of the present disclosure address the drawbacks or prior reactor systems and methods are described in greater detail below, in general, exemplary reactor systems and methods in accordance with the present disclosure include one or more process modules, wherein one or more of the process modules include a plurality of reaction chambers. As set forth in more detail below, two or more reaction chambers within a module can be used to deposit one or more of indium oxide, gallium oxide, zinc oxide, or the like. Other reaction chambers within the module and/or within another module can be used to treat a surface of a substrate prior to depositing a layer comprising indium gallium zinc oxide and/or to treat the deposited layer comprising indium gallium zinc oxide.

In accordance with exemplary embodiments of the disclosure, a reactor system includes a plurality of process modules, wherein at least one process module comprises a first reaction chamber, a second reaction chamber, and a third reaction chamber; a substrate handling chamber for providing a substrate to two or more of the plurality of process modules; and a controller. In accordance with examples of these embodiments, the first reaction chamber is configured to deposit a layer comprising InO on a surface of the substrate, the second reaction chamber is configured to deposit a layer comprising ZnO on a surface of the substrate, the third reaction chamber is configured to deposit a layer comprising GaO on a surface of the substrate, and the first reaction chamber, the second reaction chamber, and the third reaction chamber are used to form a layer comprising indium gallium zinc oxide. In accordance with further examples of the disclosure, the reactor system includes a fourth reaction chamber configured to perform one or more of a pre-deposition treatment on the surface of the substrate and a post-deposition treatment of the layer comprising indium gallium zinc oxide. The pre-deposition treatment can include one or more of a remote plasma process and a direct plasma process. Similarly, the post-deposition treatment can include one or more of a remote plasma process and a direct plasma process. Additionally or alternatively, one or more of the first reaction chamber, the second reaction chamber, the third reaction chamber, and the fourth reaction chamber can be further configured to perform one or more of a pre-deposition treatment on the surface of the substrate and a post-deposition treatment of the layer comprising indium gallium zinc oxide. Unless otherwise noted, the first, second, third, and a fourth reaction chambers can be used in any order.

In accordance with additional embodiments of the disclosure, a method of forming a layer comprising indium gallium zinc oxide is provided. An exemplary method includes the steps of providing a process module comprising a first reaction chamber, a second reaction chamber, and a third reaction chamber; forming a layer comprising InO on a surface of a substrate within the first reaction chamber, forming a layer comprising GaO on a surface of a substrate within the second reaction chamber, and forming a layer comprising ZnO on a surface of a substrate within the third reaction chamber. Unless otherwise noted, steps described herein can be performed in any suitable order. The layer comprising InO, the layer comprising GaO, and the layer comprising ZnO form a layer comprising indium gallium zinc oxide. In accordance with aspects of these embodiments, the method can include a step of forming an additional metal oxide within a fourth reaction chamber. In accordance with further aspects, the method can include a step of performing one or more of a pre-deposition treatment on the surface of the substrate and a post-deposition treatment of the layer comprising indium gallium zinc oxide within a fourth reaction chamber. The post-deposition treatment can include exposing the layer comprising indium gallium zinc oxide to activated species, such as ozone. In the case of ozone, an amount of nitrogen-containing gas used to form the ozone can be varied during the step of exposing the layer. Additionally or alternatively, a combination of a low-frequency plasma process and a remote plasma process can be used to treat a surface during a post-deposition treatment step. The pre-deposition treatment can include exposing the substrate to a reducing gas, which can be used to form excited species.

In accordance with yet further examples of the disclosure, another method is provided. The method includes providing a process module comprising a plurality of reaction chambers, providing two or more metal precursors to a first reaction chamber within a first process module, wherein the metal precursors are selected from the group consisting of an indium precursor, a gallium precursor, a zinc precursor, and an aluminum precursor, and providing an oxidant to the first reaction chamber to form an oxide comprising at least two of In, Ga, Zn, and Al. The method can further include a step of using dose control to provide one or more precursors to a reaction chamber.

In accordance with yet additional examples of the disclosure, a method of forming a layer comprising indium gallium zinc oxide is provided. The method includes forming an indium oxide layer by providing an indium reactant and a first oxidant to a reaction chamber, forming a gallium oxide layer by providing a gallium reactant and a second oxidant, and forming a zinc oxide layer by providing a zinc reactant and a third oxidant, wherein at least two of the first oxidant, the second oxidant, and the third oxidant differ. In accordance with further examples of these embodiments, at least two of the steps of forming an indium oxide layer, forming a gallium oxide layer, and forming a zinc oxide layer are performed within different reaction chambers of a process module.

These and other embodiments will become readily apparent to those skilled in the art from the following detailed description of certain embodiments having reference to the attached figures; the invention not being limited to any particular embodiment(s) disclosed. Further, both the foregoing summary and the following detailed description are exemplary and explanatory only and are not restrictive of the disclosure or the claimed invention.

### BRIEF DESCRIPTION OF THE DRAWING FIGURES

A more complete understanding of exemplary embodiments of the present disclosure can be derived by referring to the detailed description and claims when considered in connection with the following illustrative figures.

FIG. 1 illustrates an exemplary reactor system in accordance with various embodiments of the disclosure.

FIG. 2 illustrates an exemplary process module of a reactor system in accordance with various embodiments of the disclosure.

FIG. 3 illustrates a reactor in accordance with various embodiments of the disclosure.

It will be appreciated that elements in the figures are illustrated for simplicity and clarity and have not necessarily been drawn to scale. For example, the dimensions of some of the elements in the figures may be exaggerated relative to other elements to help to improve the understanding of illustrated embodiments of the present disclosure.

### DETAILED DESCRIPTION OF EXEMPLARY EMBODIMENTS OF THE DISCLOSURE

The description of exemplary embodiments provided below is merely exemplary and is intended for purposes of illustration only; the following description is not intended to limit the scope of the disclosure or the claims. Moreover, recitation of multiple embodiments having stated features is not intended to exclude other embodiments having additional features or other embodiments incorporating different combinations of the stated features.

As set forth in more detail below, various embodiments of the disclosure relate to reactor systems and methods for forming layers comprising indium gallium zinc oxide. Exemplary methods and systems allow for precise control of composition and thickness of layers comprising indium gallium zinc oxide, both within a deposited layer and across layers deposited on multiple substrates. As further set forth below, exemplary systems and methods can also include pre-deposition treatment and/or post-deposition treatment apparatus or steps.

In this disclosure, “gas” can include material that is a gas at normal temperature and pressure (NTP), a vaporized solid and/or a vaporized liquid, and can be constituted by a single gas or a mixture of gases, depending on the context. A gas other than a process gas, i.e., a gas introduced without passing through a gas distribution assembly, other gas distribution device, or the like, can be used for, e.g., sealing the reaction space, and can include a seal gas, such as a rare gas. A gas can include a single gas or a mixture of gases, depending on context.

The term “precursor” can refer to a compound that participates in the chemical reaction that produces another compound. The term “reactant” can be used interchangeably with the term precursor. The term “inert gas” can refer to a gas that does not take part in a chemical reaction and/or does not become a part of a layer to an appreciable extent. Exemplary inert gases include helium and argon and any combination thereof. In some cases, molecular nitrogen and/or hydrogen can be an inert gas. A carrier gas can be or include an inert gas.

As used herein, the term “substrate” may refer to any underlying material or materials that may be used to form, or upon which, a device, a circuit, or a film may be formed. A substrate can include a bulk material, such as silicon (e.g., single-crystal silicon), other Group IV materials, such as germanium, or compound semiconductor materials, such as GaAs, and can include one or more layers overlying or underlying the bulk material. Further, the substrate can include various topologies, such as recesses, lines, and the like formed within or on at least a portion of a layer of the substrate.

The term “cyclic deposition process” or “cyclical deposition process” can refer to the sequential introduction of precursors (and/or reactants) into a reaction chamber to deposit a layer over a substrate and includes processing techniques, such as atomic layer deposition (ALD), cyclical chemical vapor deposition (cyclical CVD), and hybrid cyclical deposition processes that include an ALD component and a cyclical CVD component. The process may comprise a purge step between introducing precursors/reactants.

The term “atomic layer deposition” can refer to a vapor deposition process in which deposition cycles, typically a plurality of consecutive deposition cycles, are conducted in a process chamber. The term “atomic layer deposition,” as used herein, is also meant to include processes designated by related terms, such as chemical vapor atomic layer deposition, when performed with alternating pulses of precursor(s)/reactive gas(es), and purge (e.g., inert carrier) gas(es).

As used herein, the term “plasma enhanced atomic layer deposition” (PEALD) may refer to an ALD process in which one or more precursors, reactants, and/or other gases are exposed to a plasma to form excited species.

As used herein, a layer comprising InO can include indium oxide and optionally additional elements. In some cases, an InO layer can consist essentially of InO (e.g., contain less than 5 at % other material). The layer comprising InO can be amorphous or crystalline and may or may not be stoichiometric.

As used herein, a layer comprising GaO can include gallium oxide and optionally additional elements. In some cases, a GaO layer can consist essentially of GaO (e.g., contain less than 5 at % other material). The layer comprising GaO can be amorphous or crystalline and may or may not be stoichiometric.

As used herein, a layer comprising ZnO can include zinc oxide and optionally additional elements. In some cases, a ZnO layer can consist essentially of ZnO (e.g., contain less than 5 at % other material). The layer comprising ZnO can be amorphous or crystalline and may or may not be stoichiometric.

As used herein, a layer comprising AlO can include aluminum oxide and optionally additional elements. In some cases, an AlO layer can consist essentially of AlO (e.g., contain less than 5 at % other material). The layer comprising AlO can be amorphous or crystalline and may or may not be stoichiometric.

A layer comprising indium gallium zinc oxide can include indium, gallium, zinc, oxygen, and optionally other elements, such as aluminum, tin, germanium, or titanium. In some cases, a layer comprising indium, gallium, zinc, oxygen can consist essentially of indium, gallium, zinc, and oxygen (e.g., contain less than 5 at % other material). The layer comprising indium, gallium, zinc, and oxygen can be amorphous or crystalline and may or may not be stoichiometric.

Further, in this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, or the like. Further, in this disclosure, the terms “including,” “constituted by” and “having” can refer independently to “typically or broadly comprising,” “comprising,” “consisting essentially of,” or “consisting of” in some embodiments. In this disclosure, any defined meanings do not necessarily exclude ordinary and customary meanings in some embodiments.

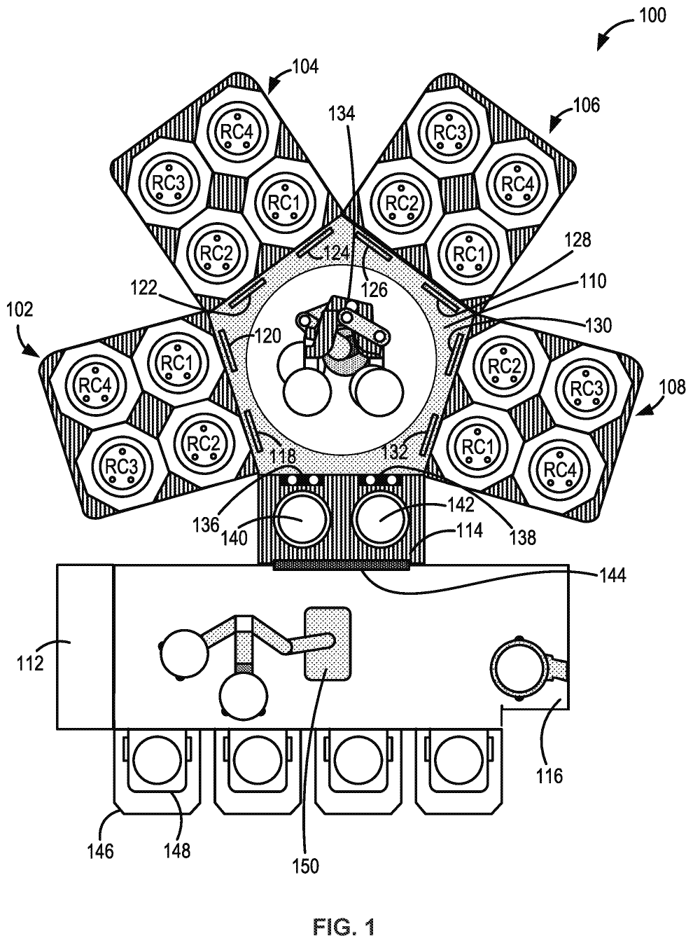

Turning now to the figures, FIG. 1 illustrates an exemplary reactor system 100 in accordance with examples of the disclosure. Reactor system 100 includes a plurality of process modules 102-108, a substrate handling chamber 110, a controller 112, a load lock chamber 114, and an equipment front end module 116.

In the illustrated example, each process module 102-108 includes four reaction chambers RC1-RC4. Unless otherwise noted, RC1-RC4 can be in any suitable order. Further, process modules in accordance with examples of the disclosure can include any suitable number of reaction chambers. Further, various process modules within a reaction system can be configured the same or differently.

In accordance with examples of the disclosure, at least one process module comprises a first reaction chamber RC1, a second reaction chamber RC2, a third reaction chamber RC3, and optionally a fourth reaction chamber RC4. In accordance with further examples, two or more (e.g., 2, 3, or 4) of process modules 102-108 include a first reaction chamber RC1, a second reaction chamber RC2, a third reaction chamber RC3, and optionally a fourth reaction chamber RC4.

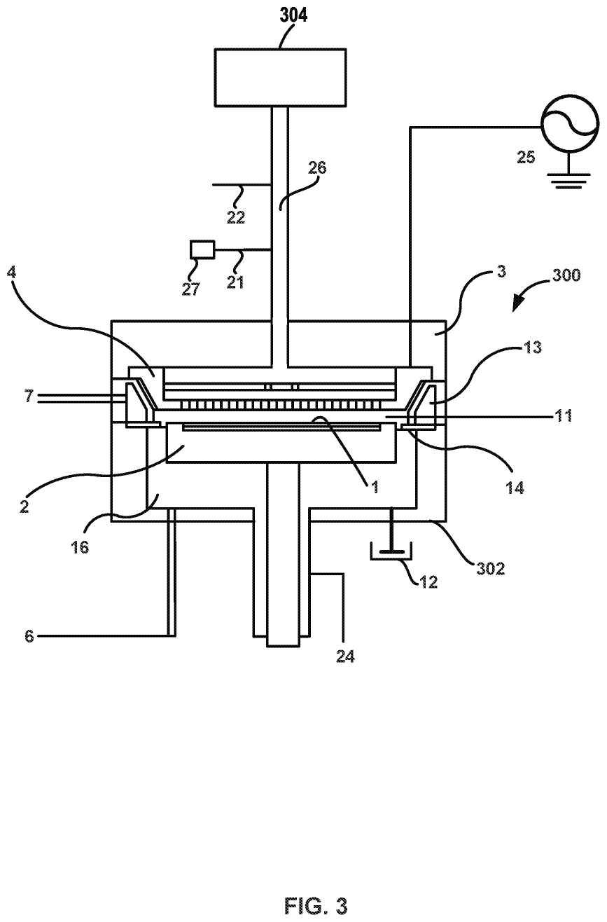

In accordance with examples of the disclosure, at least one process module 102-108 comprises a first reaction chamber RC1 configured to deposit a layer comprising InO on a surface of the substrate, a second reaction chamber RC2 configured to deposit a layer comprising ZnO on a surface of the substrate, and a third reaction chamber RC3 configured to deposit a layer comprising GaO on a surface of the substrate. First reaction chamber RC1, second reaction chamber RC2, and third reaction chamber RC3 can thus be used to form a layer comprising indium gallium zinc oxide in a single process module. In some cases, two or more (e.g., 2, 3, or 4) process modules are similarly configured. Alternatively, two or more (e.g., all) reaction chambers within a process module can perform the same reaction (e.g., deposition of the same oxide, pre-deposition treatment, and/or post-deposition treatment). In accordance with yet further examples, the same reaction chamber can perform both pre-deposition treatment and post-deposition treatment processes. Additionally or alternatively, one or more reaction chambers RC1-RC4 used to deposit a layer can also be used for pre-deposition treatment and/or post-deposition treatment. Exemplary reaction chambers are discussed in more detail below in connection with FIG. 3.

Substrate handling chamber 110 couples to each process module 102-108. By way of example, substrate handling chamber 110 can couple to each process module 102-108 via gate valves 118-132. In accordance with examples of the disclosure, process module 102-108 can be coupled to and decoupled from substrate handling chamber 110.

Substrate handling chamber 110 can be used to move substrates between load lock chamber 114 and one or more process modules 102-108 and/or between process modules 102-108. Substrate handling chamber 110 can include a back end robot 134. Back end robot 134 can transport substrates from load lock chamber 114 (e.g., stages 140, 142 therein) and any one of the susceptors within any of the reaction chambers. Back end robot 134 can be or include, for example, a multi joint robot. By way of example, back end robot 134 can retrieve and move a substrate to be transported using electrostatic or vacuum force. Back end robot 134 can be, for example, an end effector.

Controller 112 can be configured to perform one or more steps or functions as described herein. Controller 112 includes electronic circuitry and software to selectively operate valves, manifolds, heaters, pumps and other components included in reactor system 100. Such circuitry and components operate to provide gases, regulate temperature, and the like to provide proper operation of reactor system 100. Controller 112 can include modules such as software and/or hardware components, which perform certain tasks. A module may be configured to reside on the addressable storage medium of the control system and be configured to execute one or more processes, such as a method described herein.

Load lock chamber 114 is connected to substrate handling chamber 110 via, for example, gate valves 136, 138 and to equipment front end module 116. Load lock chamber 114 can include one or more, e.g., two stages 140, 142 for staging substrates between equipment front end module 116 and substrate handling chamber 110.

Equipment front end module 116 is coupled to load lock chamber 114 via an opening 144. Front end module 116 can suitably include one or more load ports 146. Load ports 146 can be provided to accommodate a substrate carrier, such as a front opening unified pod (FOUP) 148. A robot 150 provided in the equipment front end module 116 can transport one or more (e.g., two at a time) substrates between FOUP 148 and the stages 140, 142 within load lock chamber 114.

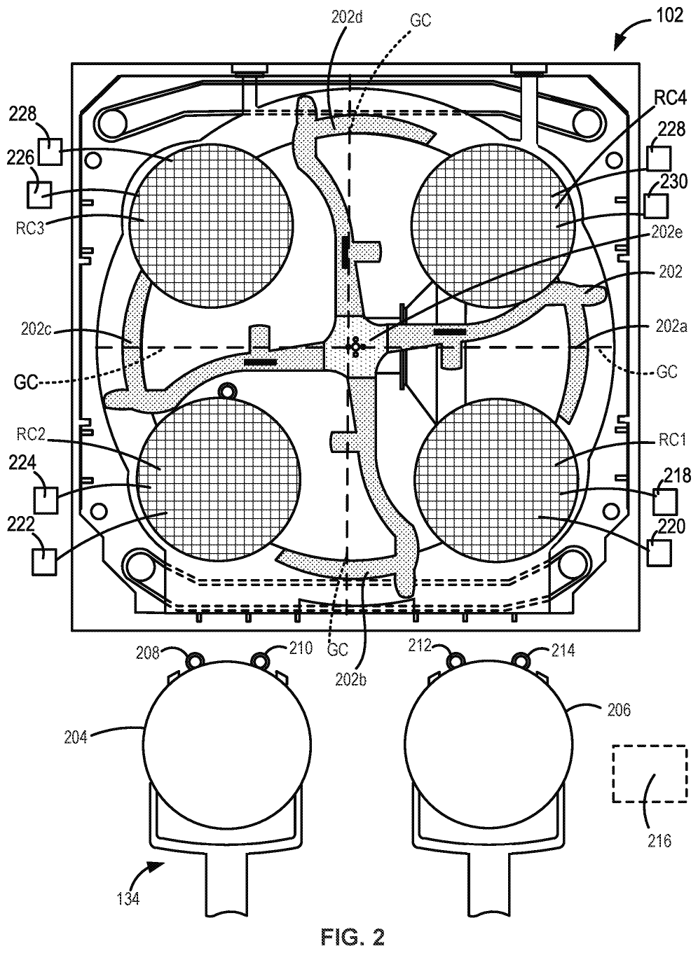

FIG. 2 illustrates a top cut-away view of an exemplary process module 102 in greater detail. In the illustrated example, process module 102 includes first reaction chamber RC1, second reaction chamber RC2, third reaction chamber RC3, and fourth reaction chamber RC4. First reaction chamber RC1 and second reaction chamber RC2 can be located at a position closer to substrate handling chamber 110 than third reaction chamber RC3 and fourth reaction chamber RC4. One or more reaction chambers RC1-RC4 can be separated from each other using one or more of a gas curtain (GC) and one or more physical barriers having an area or opening (which may be sealable) to allow substrates therethrough. Additionally or alternatively, product and process gas flows can be configured, such that desired reactions take place within and substantially only within each reaction chamber. In accordance with examples of the disclosure, substrate handling chamber 110 can communicate directly or via a gate valve(s) (e.g., gate valves 118, 120) with RC1 and RC2.

In the illustrated example, process module 102 includes a transfer arm 202 to move substrates between reaction chambers RC1-RC4 within process module 102. Transfer arm 202 can include a first through n arm for each reaction chamber. For example, transfer arm 202 can include a first arm 202a, a second arm 202b, a third arm 202c, a fourth arm 202d, and a shaft 202e. First arm 202a, second arm 202b, third arm 202c, and fourth arm 202d are supported by 202e, and rotated by rotation of the shaft 202e. Arms 202a-202d are located between the reaction chambers or inside a specific reaction chamber according to the rotational state of the shaft 202e. Transfer arm 202 can be used to provide a substrate onto a susceptor within a reaction chamber and take out a substrate on the susceptor. Transfer arm 202 can serve as a rotation arm for moving a substrate in one of the first to fourth reaction chambers RC1-RC4 into another reaction chamber. Such a rotation arm rotates, for example, counterclockwise by degrees calculated by 360/number of reaction chambers. Process modules 104-108 may be configured to have the same or similar configuration as process module 102, illustrated in FIG. 2.

In accordance with further examples of the disclosure, as illustrated in FIG. 2, back end robot 134 can transfer substrates 204, 206 to/from RC1 and RC2. One or more sensors 208-214 can be provided in a region between substrate handling chamber 110 and the process module 102. For example, two sensors 208, 210 can be provided in front of first reaction chamber RC1, and two sensors 212, 214 can be provided in front of second reaction chamber RC2. One or more sensors 208-214 can include a light emitting element and a light sensing element that overlap each other (e.g., in a vertical direction). The light emitting element can emit (e.g., laser) light in a positive or negative direction, and the light sensing element detects the (e.g., laser) light. The presence or absence of a substrate between the light emitting element and the light sensing element can be detected based on reception or non-reception of light by the light receiving element. For example, the light receiving element can output a high-level signal when it senses a threshold amount of light, and output a low-level signal when it receives no or below a threshold level amount of light. The light sensing element can provide an output of a waveform corresponding to the passage condition of a substrate.

Process module 102 can also include an automatic substrate sensing unit for determining whether a substrate has passed a predetermined position when the substrate is transferred from substrate handling chamber 110 to first reaction chamber RC1 or second reaction chamber RC2 by back end robot 134. The automatic wafer sensing unit can include, for example, the aforementioned sensors 208-214 and a transfer module controller (TMC) 216 connected to the sensors 208-214. TMC 216 can be located, for example, under substrate handling chamber 110. TMC 216 can compare a detection result of one or more sensors 208-214 with a predetermined waveform to determine whether the substrate has passed the predetermined position. In this way, it is possible to perform detection of abnormal transfer by the automatic wafer sensing unit when a substrate is transferred in a direction from substrate handling chamber 110 to first reaction chamber RC1 or second reaction chamber RC2 or when a substrate is transferred in the opposite direction. The abnormal transfer may be caused by misalignment of the substrate with respect to back end robot 134, cracking of the substrate, or the like. According to an example, it is possible for TMC 216 to realize a correction function for correcting a transfer destination when abnormal transfer is detected.

More detailed descriptions of exemplary process modules suitable for process modules 102-108 and exemplary systems are provided in U.S. Pat. No. 10,777,445 in the name of Kazuhiro Nishiwaki, issued Sep. 15, 2020; U.S. Pat. No. 10,332,767 in the name of Taku Omori, issued Jun. 25, 2019; and U.S. application Ser. No. 17/169,440, filed Feb. 6, 2021, and titled REACTOR SYSTEM WITH MULTI-DIRECTIONAL REACTION CHAMBER, the contents of which are hereby incorporated herein by reference.

One or more precursor sources and one or more oxidant sources can be coupled to each reaction chamber RC1-RC4. In the illustrated example, a first precursor source (e.g., comprising an indium precursor) 218 and a first oxidant source 220 are fluidly coupled to RC1; a second precursor source (e.g., comprising a zinc precursor) 222 and a second oxidant source 224 are fluidly coupled to RC2; a third precursor source (e.g., comprising a gallium precursor) 226 and a third oxidant source 228 are fluidly coupled to RC3; and a fourth precursor source (e.g., comprising an aluminum or other metal precursor) 228 and a fourth oxidant source 230 are fluidly coupled to RC4. In some cases, RC4 may not include a precursor source. In such cases, RC4 can be used for pre-deposition treatment and/or post-deposition treatment as described herein, and reactant source 230 can comprise a gas used for treatment (e.g., to form a plasma) as described herein.

Turning now to FIG. 3, an exemplary reaction chamber 300 suitable for use as one or more reaction chambers RC1-RC4 is illustrated. Reaction chamber 300 is illustrated as a PEALD reactor. However, reaction chamber 300 can alternatively be configured as a thermal or gas-phase reactor. Various reaction chambers described herein can be used for CVD, cyclical deposition (e.g., ALD), which may be thermal (i.e., no plasma or active species formed) or plasma or active-species assisted.

As illustrated in FIG. 3, by providing a pair of electrically conductive flat-plate electrodes 2,4 that can be configured in parallel and facing each other in an interior 11 (reaction zone) of a reaction chamber 300, applying RF power (e.g., at 13.56 MHz and/or 27 MHz) from a power source 25 to one side, and electrically grounding the other side 12, a plasma can be generated between electrodes 2,4. A temperature regulator may be provided in a lower stage 2, i.e., the lower electrode. A substrate 1 can be placed thereon and the substrate temperature can be controlled at desired temperature(s). Upper electrode 4 can serve as a gas distribution device, such as a shower plate, as well as various gases, such as a plasma gas, a reactant gas and/or a dilution gas, if any, as well as a gas mixture can be introduced into the reaction chamber 300 through a gas line 21 and a gas line 22, and through the shower plate 4. For example, a precursor or gas mixture (e.g., comprising two or more precursors) can be provided to a gas injection port 26 via line 22 and a reactant (e.g., an oxidant) from a reactant source 27 can be provided to gas injection port 26 via line 21. In some cases, a remote plasma unit 304 can be used to provide active species to reaction zone 11.

In reaction chamber 300, a duct 13 with an exhaust line 17 can be provided, through which the gas in the interior 11 of the reaction chamber 300 can be exhausted. A gas seal line 24 can be used to introduce seal gas into the interior 11 of the reaction chamber 300, wherein a separation plate 14 is provided. An opening, such as a gate valve through which the substrate may be transferred into reaction chamber 300, is omitted from this figure. A purge area 16 can also be provided with an exhaust line 6. In the illustrated example, reaction chamber 300 includes a housing 302 to isolate the reaction chamber from an environment and/or another reaction chamber. Additionally or alternatively, as noted above, a gas curtain can be used to facilitate isolation of one reaction chamber from one or more other reaction chambers.

As noted above, in accordance with various embodiments of the disclosure, a process module, such as process module 102, can be configured, such that a first reaction chamber is configured to deposit a layer comprising InO on a surface of the substrate, a second reaction chamber is configured to deposit a layer comprising ZnO on a surface of the substrate, and a third reaction chamber is configured to deposit a layer comprising GaO on a surface of the substrate, wherein the first reaction chamber, the second reaction chamber, and the third reaction chamber are used to form a layer comprising indium gallium zinc oxide. As illustrated in FIGS. 1 and 2, a process module can additionally include a fourth reaction chamber. The fourth reaction chamber can be configured to perform one or more of a pre-deposition treatment on the surface of the substrate, a post-deposition treatment of the layer comprising indium gallium zinc oxide, or deposition of another layer, such as another metal (e.g., Al) oxide.

The layers comprising InO, ZnO, and/or GaO can be formed using a thermal or a plasma-assisted process. The thermal or plasma process can include providing a metal precursor (e.g., one or more of In, Zn, and Ga) precursor and an oxidant to a reaction (e.g., distinct) reaction chamber.

Exemplary indium precursors suitable for use in accordance with examples of the disclosure include at least one of: TEI; TMI; 3-(dimethylamino)propyl]dimethyl-indium (DADI); cyclopentadienylindium(I); In(acac)₃; In(dmamp)₂(OⁱPr); In(dmamp)₃; In(dpguan)₃; In(EtCp); InCp; In(iPrAMD)₃; In(iPrFMD)₃; In(N(SiMe₃)₂)Et₂; In(PrNMe₂)Me₂; In(thd)₃; InCl₃; InMe₂(edpa); InMe₃(MeO(CH₂)₂NHtBu); InMe₃; or InEt₃. Exemplary zinc precursors suitable for use in accordance with examples of the disclosure include at least one of: DEZ, DMZ; [EtZn(damp)]₂; Zn(DMP)₂; Zn(eeki)₂; Zn(OAc)₂; ZnCl₂; ZnEt₂; ZnMe₂; or ZnMe(OⁱPr). Exemplary gallium precursors suitable for use in accordance with examples of the disclosure include at least one of: TDMAGa; TMGa; TEGa; GaCl₃; GaEt₂Cl; (GaMe₂NH₂)₃; Ga(acac)₃; Ga(CpMe₅); Ga(thd); Ga₂(NMe₂)₆; GaMe₂(OⁱPr); GaMe₂NH₂; or GaMe₃(CH₃OCH₂CH₂NHtBu). Exemplary oxidants include water, ozone, an alcohol, peroxide, H₂O₂, oxygen plasma, hydrogen plasma, or in-situ —OH radicals, for example. In accordance with examples of the disclosure, an oxidant can be selected based on, for example, a desired thickness/deposition cycle. Thus, a composition of the layer comprising indium gallium zinc oxide can be manipulated by choice of an oxidant used to deposit one or more oxides. In accordance with examples of the disclosure, at least two different oxidants are provided to one or more of the reaction chambers within a process module, such that at least two of a first oxidant that reacts with the indium precursor to form indium oxide, a second oxidant that reacts with the zinc precursor to form zinc oxide, and a third oxidant that reacts with the gallium precursor to form gallium oxide differ. In other cases, the first, second and/or third oxidants can be the same oxidant. Additionally or alternatively, an inhibitor, such as an alkyl alcohol (e.g., methanol, ethanol, isopropanol, n-butanol, alcohol, tert-butanol, or the like), a carboxylic acid, a ketone, an aldehyde, and/or a beta-diketone can be used during deposition cycles to obtain desired thickness/cycle of one or more oxides. Additionally or alternatively, reaction chamber or susceptor temperatures can be controlled to obtain desired deposition rates/cycle and/or composition of various oxide layers.

In accordance with some examples, particularly for thermal deposition process (e.g., using ozone as a reactant), an order of the steps of depositing the layers can be, in order: GaO, ZnO, and InO. This order of deposition showed significant improvement in step coverage of indium gallium zinc oxide overlying features, such as features having the aspect ratios noted below. For example, an improvement from about 80% to about 95% step coverage of thermally-deposited indium gallium zinc oxide was observed using a deposition order of GaO, ZnO, and InO, compared to a deposition order of GaO, InO, and ZnO. In addition to improving step coverage, a deposition order of GaO, ZnO, and InO is thought to improve composition uniformity for indium gallium zinc oxide layers formed within a feature. Exemplary aspect ratios of features (e.g., trenches) are greater than 10, 20, 25, 30, or 50; the aspect ratios can additionally or alternatively be less than 200 or less than 100 or less than 75 or less than 50.

In accordance with further examples of the disclosure, a reaction chamber (e.g., RC4) within a process module 102-108 is configured to perform a pre-deposition treatment. The pre-deposition treatment can include one or more of a remote plasma process and a direct plasma process. In these cases, a plasma can be formed using a gas, such as H₂, O₂, forming gas (N₂ and H₂), ozone, UV technique gases, NH, hydrazine, hydrazine derivatives. Additionally or alternatively, a reaction chamber (e.g., RC4) can be configured to perform a post-deposition treatment. The post-deposition treatment comprises one or more of a remote plasma process and a direct plasma process. In these cases, a plasma can be formed using a gas, such as annealing gases, plasma densification gases, oxidizing or reducing gases, or nitridation gases. Additionally or alternatively, as noted above, one or more of a first reaction chamber RC1, a second reaction chamber RC2, and a third reaction chamber RC3 of a process module 102-108 can be further configured to perform one or more of a pre-deposition treatment on the surface of the substrate and a post-deposition treatment of the layer comprising indium gallium zinc oxide—e.g., using a technique as described above.

In accordance with further examples of the disclosure, at least one process module 102-108 comprises a fourth reaction chamber RC4 configured to deposit a layer comprising another metal or metal oxide, such as aluminum oxide, tin oxide, or titanium oxide.

In accordance with further examples of the disclosure, each reaction chamber RC1-RC4 within a process module—e.g., a susceptor within each module—can be independently controlled—e.g., using controller 112. For example, a temperature within the first reaction chamber can be between 100 and 400° C., a temperature within the second reaction chamber can be between 75 and 450° C., and a temperature within the third reaction chamber can be between 50 and 500° C. By controlling a temperature, a growth rate per cycle within each reaction chamber can be controlled.

In accordance with additional examples of the disclosure, a method of forming a layer comprising indium gallium zinc oxide is provided. An exemplary method includes providing a process module (e.g., process module 102), forming a layer comprising InO on a surface of a substrate within a first reaction chamber of the process module, forming a layer comprising GaO on a surface of a substrate within a second reaction chamber of the process module, and forming a layer comprising ZnO on a surface of a substrate within the third reaction chamber of the process module. The layer comprising InO, the layer comprising GaO, and the layer comprising ZnO can form a layer comprising indium gallium zinc oxide. An exemplary method can further include a step of forming an additional metal oxide within a fourth reaction chamber of the process module. The additional metal oxide can include, for example, one or more of aluminum oxide, tin oxide, or titanium oxide. In some cases, an order of the steps of forming layers can be as noted above, i.e., GaO, ZnO, and then InO.

In accordance with further examples, the method can include a step of performing one or more of a pre-deposition treatment on the surface of the substrate and a post-deposition treatment of the layer comprising indium gallium zinc oxide within a (e.g., fourth) reaction chamber of the process module.

The pre-deposition treatment step can be used to, for example, remove contaminants, such as carbon, from a surface of a substrate. The pre-deposition treatment step can include a thermal and/or a plasma process. In accordance with examples of the disclosure, the pre-deposition treatment includes exposing the substrate to a reducing gas. Exemplary reducing gases include hydrogen, ammonia, hydrazine, or hydrazine derivatives. In some cases, reactive species are formed using the reducing gas—e.g., using a direct and/or remote plasma.

The post-deposition treatment can be used to, for example, tune properties of the layer comprising indium gallium zinc oxide. Exemplary post-deposition treatment steps include plasma treatment of the layer comprising indium gallium zinc oxide. The plasma can include a direct plasma and/or a remote plasma. In some cases, the post-deposition treatment includes a low-frequency (e.g., approximately 700 Hz, for example) (e.g., direct) plasma process and a remote plasma process. The gas(es) used to form the direct and/or remote plasma include oxygen, nitrogen, hydrogen, ammonia, hydrazine, or hydrazine derivatives. By way of examples, the post-deposition treatment can include exposing the layer comprising indium gallium zinc oxide to ozone formed using one or more nitrogen-containing gases (e.g., nitrogen, ammonia, hydrazine, or hydrazine derivatives) and/or one or more oxygen-containing gases (e.g., water, ozone, an alcohol, peroxide, H₂O₂, oxygen plasma, hydrogen plasma, or in-situ —OH radicals). In such cases, an amount of nitrogen-containing gas used to form the ozone can be manipulated during the step of exposing the layer comprising indium gallium zinc oxide to ozone.

In accordance with yet additional examples of the disclosure, a method can include asymmetrically or non-uniformly providing one or more precursors to the surface of a substrate. For example, the method can include providing one or more of a first precursor comprising In, a second precursor comprising Ga, and a third precursor comprising Zn non uniformly from a center of a substrate to an edge of the substrate within one or more reaction chambers (e.g., RC1-RC4).

In accordance with further examples of the disclosure, two or more (e.g., In, Ga, Zn, Al) oxide layers or layers comprising two or more of such oxides can be formed within a single reaction chamber. In these cases, a method can include providing a process module comprising a plurality of reaction chambers, providing two or more precursors (e.g., In, Ga, Zn, Al) to a first reaction chamber within a first process module, wherein the metal precursors are selected from the group consisting of an indium precursor, a gallium precursor, a zinc precursor, and an aluminum precursor, and providing an oxidant to the first reaction chamber to form an oxide comprising at least two of In, Ga, Zn, and Al.

Exemplary methods described herein can include a step of dose control for one or more of the precursors prior to the precursors entering the first reaction chamber. The dose control can be performed using, for example, fast switching valves to control pulse times and concentrations.

Although exemplary embodiments of the present disclosure are set forth herein, it should be appreciated that the disclosure is not so limited. For example, although the reactors, reactor systems, and methods are described in connection with various specific configurations, the disclosure is not necessarily limited to these examples. Indeed, unless otherwise noted, features and components of various reactors, systems, and methods described herein can be interchanged. Various modifications, variations, and enhancements of the reactors, systems, and methods set forth herein may be made without departing from the spirit and scope of the present disclosure.

The subject matter of the present disclosure includes all novel and nonobvious combinations and subcombinations of the various systems, assemblies, reactors, components, and configurations, and other features, functions, acts, and/or properties disclosed herein, as well as any and all equivalents thereof.

We claim:

1. A reactor system comprising:
a plurality of process modules, wherein at least one process module comprises a first reaction chamber, a second reaction chamber, and a third reaction chamber;
a substrate handling chamber for providing a substrate to two or more of the plurality of process modules; and
a controller,
wherein the first reaction chamber of the at least one process module is configured to deposit a layer comprising InO on a surface of the substrate,
wherein the second reaction chamber of the at least one process module is configured to deposit a layer comprising ZnO on a surface of the substrate,
wherein the third reaction chamber of the at least one process module is configured to deposit a layer comprising GaO on a surface of the substrate, and
wherein the first reaction chamber, the second reaction chamber, and the third reaction chamber are used to form a layer comprising indium gallium zinc oxide.

2. The reactor system of claim 1, wherein the at least one process module further comprises a fourth reaction chamber configured to perform one or more of a pre-deposition treatment on the surface of the substrate and a post-deposition treatment of the layer comprising indium gallium zinc oxide.

3. The reactor system of claim 2, wherein the fourth reaction chamber is configured to perform the pre-deposition treatment, wherein the pre-deposition treatment comprises one or more of a remote plasma process and a direct plasma process.

4. The reactor system of claim 2, wherein the fourth reaction chamber is configured to perform the post-deposition treatment, wherein the post-deposition treatment comprises one or more of a remote plasma process and a direct plasma process.

5. The reactor system of claim 1, wherein one or more of the first reaction chamber, the second reaction chamber, and the third reaction chamber are further configured to perform one or more of a pre-deposition treatment on the surface of the substrate and a post-deposition treatment of the layer comprising indium gallium zinc oxide.

6. The reactor system of claim 1, wherein the at least one process module further comprises a fourth reaction chamber configured to deposit a layer comprising aluminum oxide.

7. The reactor system of claim 1, wherein the controller controls a temperature within the first reaction chamber between 100 and 400° C., controls a temperature within the second reaction chamber between 75 and 450° C., and controls a temperature within the third reaction chamber between 50 and 500° C.

8. The reactor system of claim 1, wherein the first reaction chamber is fluidly coupled to an indium gas source; the second reaction chamber is coupled to a gallium gas source; the third reaction chamber is coupled to a zinc gas source, and two or more of the first reaction chamber, the second reaction chamber, and the third reaction chamber are coupled to an oxygen gas source.

9. A method of forming a layer comprising indium gallium zinc oxide, the method comprising the steps of:
providing a process module comprising a first reaction chamber, a second reaction chamber, and a third reaction chamber;
forming a layer comprising InO on a surface of a substrate within the first reaction chamber;
forming a layer comprising GaO on a surface of a substrate within the second reaction chamber; and
forming a layer comprising ZnO on a surface of a substrate within the third reaction chamber,
wherein the layer comprising InO, the layer comprising GaO, and the layer comprising ZnO form a layer comprising indium gallium zinc oxide.

10. The method of claim 9, further comprising a step of forming an additional metal oxide within a fourth reaction chamber.

11. The method of claim 9, further comprising a step of performing one or more of a pre-deposition treatment on the surface of the substrate and a post-deposition treatment of the layer comprising indium gallium zinc oxide within a fourth reaction chamber.

12. The method of claim 11, wherein the post-deposition treatment comprises exposing the layer comprising indium gallium zinc oxide to ozone, wherein an amount of nitrogen-containing gas used to form the ozone varies during the step of exposing the layer.

13. The method of claim 9, wherein the post-deposition treatment comprises a low-frequency plasma process and a remote plasma process.

14. The method of claim 11, wherein the pre-deposition treatment comprises exposing the substrate to a reducing gas.

15. The method of claim 14, wherein excited species are formed using the reducing gas.

16. The method of claim 9, wherein a gas distribution of one or more of a first precursor comprising In, a second precursor comprising Ga, and a third precursor comprising Zn are distributed non uniformly from a center of a substrate to an edge of the substrate.

17. A method of forming a layer comprising indium gallium zinc oxide, the method comprising:
providing a process module comprising a plurality of reaction chambers;
providing two or more precursors to a first reaction chamber within a first process module, wherein the two or more precursors are selected from the group consisting of an indium precursor, a gallium precursor, a zinc precursor, and an aluminum precursor; and
providing an oxidant to the first reaction chamber to form an oxide comprising at least two of In, Ga, Zn, and Al.

18. The method of claim 17, further comprising a step of using dose control for one or more of the precursors prior to the precursors entering the first reaction chamber.

19. A method of forming a layer comprising indium gallium zinc oxide, the method comprising:
forming an indium oxide layer by providing an indium reactant and a first oxidant to a reaction chamber;
forming a gallium oxide layer by providing a gallium reactant and a second oxidant; and
forming a zinc oxide layer by providing a zinc reactant and a third oxidant,
wherein at least two of the first oxidant, the second oxidant, and the third oxidant differ.

20. The method of claim 19, wherein at least two of the steps of forming an indium oxide layer, forming a gallium oxide layer, and forming a zinc oxide layer are performed within different reaction chambers of a process module.

21. The method of claim 9, wherein the steps are performed in the following order:
forming the layer comprising GaO or forming the gallium oxide layer;
forming the layer comprising ZnO or forming the zinc oxide layer; and
forming the layer comprising InO or forming the indium oxide layer.
